(19) United States
(12) Patent Application Publication
(10) Pub. No.: US 2013/0258615 A1
(43) Pub. Date: Oct. 3, 2013

(54) METHOD FOR PRODUCING AN ELECTRONIC ASSEMBLY HAVING A SHAPED BODY

(71) Applicant: Gerhard Grauf, Lichtenstein-Unterhausen (DE)

(72) Inventor: Gerhard Grauf, Lichtenstein-Unterhausen (DE)

(73) Assignee: ROBERT BOSCH GMBH, Stuttgart (DE)

(21) Appl. No.: 13/994,601

(22) PCT Filed: Dec. 9, 2011
(86) PCT No.: PCT/EP2011/072355

§ 371 Date: Jun. 14, 2013

(30) Foreign Application Priority Data
Dec. 14, 2010 (DE) 10 2010 063 048.9

(51) Int. Cl. H05K 3/30; H05K 1/18

(52) U.S. Cl. CPC H05K 3/30; H05K 1/18
USPC 361/748; 29/832

(57) ABSTRACT

The invention relates to a method for producing an electronic assembly (1) having at least one electronic component (3, 4) and a shaped body (2) which at least partially surrounds the electronic component (3, 4), comprising the following steps: at least one electronic component (3, 4) is placed into an open mould (10), a first moulding material (21) and a second moulding material (22) are supplied to a cavity (13) in the mould (10), wherein the first moulding material is different from the second moulding material, and the mould (10) is closed, wherein the mould (10) is closed before or at the same time as the first and second moulding materials (21, 22) are supplied.

### BACKGROUND OF THE INVENTION

The present invention relates to a method for producing an electronic assembly having a shaped body and to such an electronic assembly.

Electronic assemblies having shaped bodies have previously been known in such a way that an electronic component such as a populated printed circuit board, or sensors, for example, on a lead frame or ceramic substrate are partly or completely surrounded by a shaped body made of molding material. In the case of completely surrounded electronic assemblies, electric contact elements are led as far as the outside of the shaped body. Since, in the known electronic assemblies, only a single molding material is used to embed the electronic components, although the latter can be produced relatively quickly in one step, no adaptations can be made to the various electronic components which, for example, generate different amounts of heat. It would therefore be desirable to provide a simple and inexpensive method for producing an electronic assembly and such an electronic assembly which corresponds to different requirements of electronic components.

### SUMMARY OF THE INVENTION

By contrast, the method according to the invention for producing an electronic assembly having at least one electronic component and a shaped body at least partly surrounding the electronic component has the advantage that two or more different molding materials can be used, which can be chosen in accordance with specific requirements of different electronic components. Provision is in particular made for the at least one electronic component to be at least partly, preferably completely, surrounded by the first molding material. Furthermore, provision is preferably made for the area of the at least one electronic component that is not surrounded by the first molding material to be at least partly, preferably completely, surrounded by the second and/or the further molding materials. Alternatively or additionally, provision is likewise preferably made for a further electronic component to be at least partly, preferably completely, surrounded by the second and/or the further molding material. “Surrounded” means in particular that the respective molding material is in direct contact with the respective electronic component. As a result of the locally distributed arrangement of the two or more molding materials for forming a shaped body, it is ensured that each electronic component is surrounded on the basis of its specific requirement in relation to, for example, heating, expansion, mechanical loading, and so on, by a molding material matched thereto. At the same time, the method according to the invention remains very economical and is in particular also suitable for large numbers. The method according to the invention comprises the steps of inserting one or more electronic components into an opened mold, supplying at least two different molding materials to a cavity in the mold and closing the mold. The mold can be closed before or at the same time as the molding materials are supplied. It should be noted that, in the event of simultaneously closing the mold and supplying the molding materials, care must be taken that the molding material cannot escape from the mold. The electronic component is preferably a printed circuit board or lead frame or ceramic substrate, on which an extremely wide range of further electronic components, e.g. sensors, chips, ICs, power transistors, capacitors, coils, resistors and so on can be arranged. The method according to the invention is particularly preferably used for producing control devices for vehicles or other electronic assemblies for vehicles.

In order to ensure particularly quick filling of the mold with the different molding materials, the molding materials are preferably supplied simultaneously.

Particularly preferably, the first molding material is supplied by a first press piston and the second molding material is supplied by a second press piston.

In order to avoid mixing of the molding materials, separating elements are preferably provided, which are placed on an electronic component or which are fixed to an electronic component, for example by means of adhesive bonding or welding or soldering, the separating elements providing, with a mold wall of the mold, a subdivision of the cavity present in the mold. The separating elements thus effect sealing on the electronic component and the mold wall, so that a clearly defined subdivision of the molding materials forming the shaped body is possible. In this way, for example, a first electronic component is surrounded by a first molding material completely as far as the outer area of the shaped body, the first molding material adjoining a separating element. Furthermore, for example, a further electronic component is surrounded by a second molding material as far as the outer area of the shaped body. The second molding material is separated from the first molding material by the one dividing wall. The separating elements are preferably made of plastic.

According to a further preferred refinement of the invention, guide elements for guiding the molding material supplied are provided in the cavity. The guide elements can be provided on the mold and/or on the electronic component and/or as a loose insert part. The guide elements permit flow guidance of the molding compounds supplied, so that, for example, specific mixing of two molding materials in desired subareas of the shaped body is possible. This results in a further possible way, by mixing two pure molding materials, of producing a third molding material having different properties during the molding operation.

For particularly rapid and uniform filling of the cavity of the mold, the first and second molding material are preferably supplied to the mold from mutually opposite sides.

The molding material used is preferably plastics having different material properties, in particular with regard to the inherent elasticity thereof

The invention further relates to an electronic assembly, such as an electronic control device for vehicles, comprising at least one electronic component, e.g. a printed circuit board having various electronic components (e.g. chips), and a shaped body at least partly surrounding the electronic component. The shaped body is produced from at least two different molding materials. The at least one electronic component is in particular at least partly, preferably completely, surrounded by the first molding material. Furthermore, the area of the at least one electronic component that is not surrounded by the first molding material is at least partly, preferably completely, surrounded by the second and/or the further molding material. Alternatively or additionally, a further electronic component is preferably at least partly, preferably completely, surrounded by the second and/or the further molding materials. In this way, individual adaptation to the specific circumstances of the various electronic components can be implemented by choosing the respective molding materials.

The electronic assembly according to the invention preferably further comprises at least one separating element, which is arranged in the shaped body and separates the first molding material from the second molding material. In this way, exact separation between the two molding materials is possible without any mixing of the molding materials. Particularly preferably, the separating element is arranged directly on an electronic component or, alternatively, the separating element is directly the electronic component itself

According to a further preferred refinement of the invention, the electronic assembly according to the invention preferably comprises at least one guide element, which is arranged in the shaped body. The guide element is used for the flow guidance of the molding material supplied during the production of the shaped body. The guide element can, firstly, define the guidance of the molding material in the mold and, secondly, also permit specific mixing of two different molding materials by means of appropriate guidance of the material flow. The guide element is preferably produced from plastic.

### BRIEF DESCRIPTION OF THE DRAWINGS

Preferred exemplary embodiments of the invention will be described in detail below with reference to the accompanying drawing, in which:

FIG. 1 shows a schematic sectional view of an electronic assembly according to a first exemplary embodiment of the invention,

FIG. 2 shows a schematic sectional view of a mold construction for producing the assembly from FIG. 1,

FIG. 3 shows a schematic plan view of a mold for producing an electronic assembly according to a second exemplary embodiment of the invention with an electronic component inserted,

FIG. 4 shows a schematic sectional view along the line III-III from FIG. 3,

FIG. 5 shows a schematic plan view corresponding to FIG. 3 with an illustration of the supply of molding materials, and

FIG. 6 shows a schematic sectional view along the line VI-VI from FIG. 5.

### DETAILED DESCRIPTION

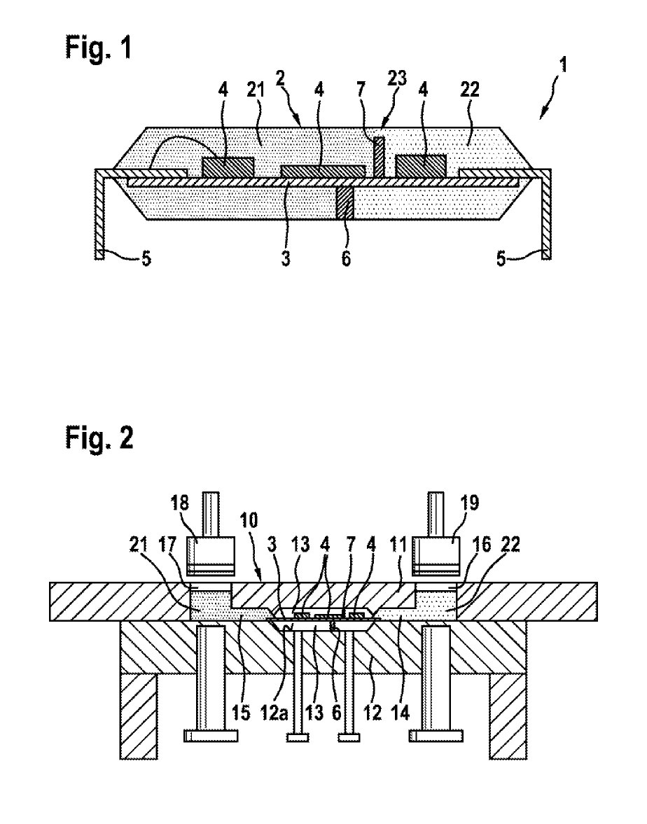

A method and an electronic assembly 1 according to first preferred exemplary embodiment of the invention will be described in detail below with reference to FIGS. 1 and 2.

As can be seen from FIG. 1, the electronic assembly comprises a shaped body 2 and a multiplicity of electronic components, in particular a printed circuit board 3 and a multiplicity of electronic elements 4 arranged on the printed circuit board. Furthermore, two line connections 5 are led out of the electronic component 1.

The shaped body 2 of the first exemplary embodiment is produced from a first molding material 21 and a second molding material 22. The molding materials are, for example, different plastics having different elastic properties. Furthermore, the electronic assembly 1 comprises a separating element 6 produced from plastic, which touches the printed circuit board 3, projects as far as the outside of the shaped body 2 and provides an exact separation between the first molding material 21 and the second molding material 22.

Furthermore, a guide element 7 is provided, which is arranged on the printed circuit board 2 but does not project as far as the outer surface of the shaped body. The guide element 7 is used to guide the flowing molding materials supplied. The result on the side oriented toward the surface of the shaped body 2 is a mixing area 23, in which mixing of the first and second molding material occurs. Depending on the configuration of the guide element 7, this mixing of the two molding materials 21 and 22 can be more highly or more weakly pronounced. Thus, by means of the guide element 7 and by means of mixing the first and second molding material, a third molding material having different properties can be provided during the molding operation.

Overall, in this practical example, an area of the underside of the printed circuit board 3 as far as the separating element 3 and as far as the lower outer surface of the shaped body 2, and also an area from the upper side of the printed circuit board 3 together with two electronic components 4 as far as the guide element 7 or mixing area 23 and as far as the upper outer surface of the shaped body 2 is surrounded by the first molding material 21. Furthermore, a further area of the underside of the printed circuit board 3, starting from the separating element 3 as far as the lower outer surface of the shaped body 2, and also an area from the upper side of the printed circuit board 3 together with two electronic components 4, starting from the guide element 7 or mixing area 23 as far as the upper outer surface of the shaped body 2, is surrounded by the second molding material 22.

FIG. 2 illustrates the production of the electronic assembly 1. As can be seen from the illustration of FIG. 2, a printed circuit board 3 populated with electronic elements 4 is inserted into a cavity 13 of the mold 10, which cavity is present between a first mold half 11 and a second mold half 12. Via channels 14, 15, the first and second molding material 21, 22 from a supply chamber 16, 17 is supplied to the cavity 13 by means of pistons 18, 19.

The separating element 6 can be inserted between the printed circuit board 3 and a mold wall 12a as an insert part, or the separating element 6 is provided fixed to the printed circuit board 3 or to the second mold half 12. The guide element 7 can likewise be provided as an insert part or the guide element 7 is alternatively fixed to the printed circuit board 3, for example by means of adhesive bonding.

The method according to the invention can be carried out in such a way that, firstly, the two mold halves 11, 12 are closed and then the first and second molding material 21, 22 is supplied to the cavity 13. Alternatively, at the same time as the start of the closing operation of the two mold halves 11, 12, the two pistons 18, 19 can also be moved and thus, a start can be made on supplying the first and second molding material 21, 22 to the cavity 13 at the same time as the start of the closing operation of the mold 10. In the case of the latter alternative, care merely has to be taken that the molding material already supplied before the complete closure of the mold does not emerge over the boundaries of the cavity.

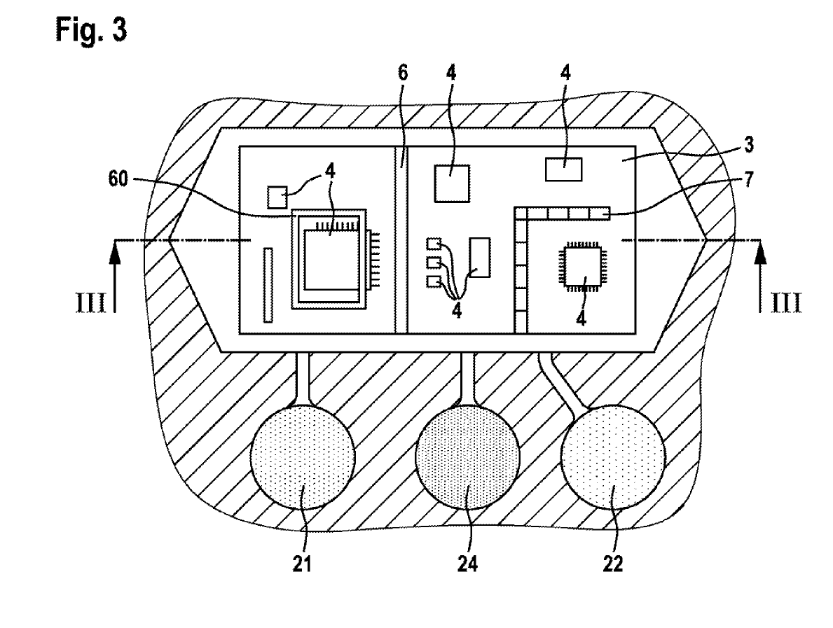

An electronic component and a method for the production thereof according to a second exemplary embodiment of the invention will be described below with reference to FIGS. 3 to 6, identical or functionally identical parts being designated by the same designations as in the first exemplary embodiment.

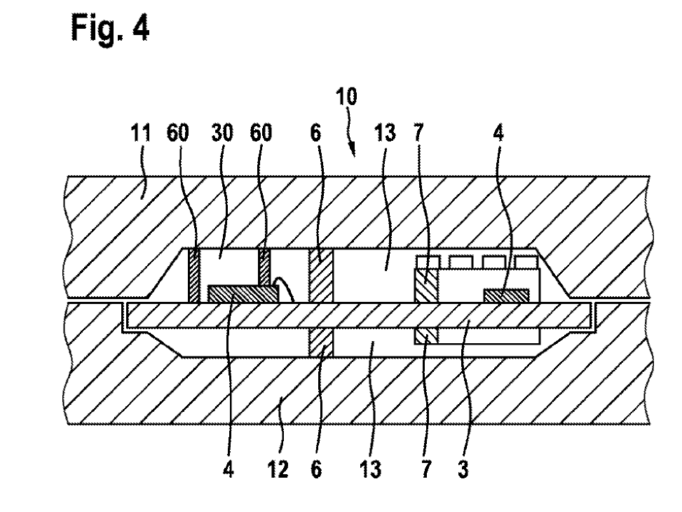

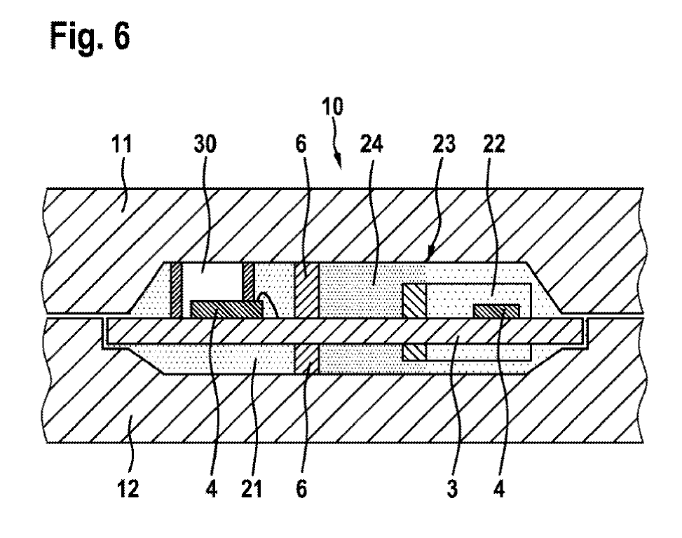

The second exemplary embodiment shows an electronic assembly and a method in which a third molding material 23 is additionally used. Thus, the electronic assembly produced in such a way has a shaped body with three different characteristics corresponding to the material properties of the three molding materials. FIGS. 3 and 4 show the state in which the electronic components, such as the printed circuit board 3 and chips 4, have been inserted into the mold 10. As a result, above and below the printed circuit board 3, cavities 13 are produced, which are joined to each other at the outer periphery. Also arranged in the printed circuit board 3 is a separating element 6 which, in this exemplary embodiment, is provided on an upper side and an underside of the printed circuit board 3. Furthermore, a third, circumferentially closed separating element 60 is arranged on the printed circuit board 3 or a chip 4, and covers a subarea of the chip 4. This produces a further cavity 30. Since the third separating element 60 is closed all round, the result in the subsequent component, as can be seen from FIG. 6, is a remaining cavity 30 which is not filled with molding material.

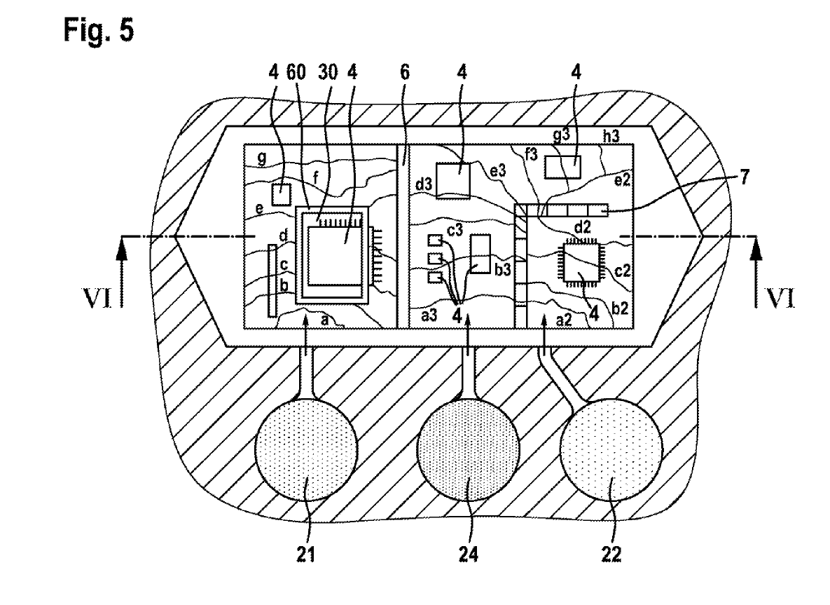

Furthermore, a guide element 7 is provided which, as can be seen in particular from FIG. 3, has a crenellated crown shape. This makes it possible for the second molding material 22 and the third molding material 24 to mix partly in the area of the guide element 7. The guide element 7 in particular influences the flow front of the shaped body compound, also in interaction with the positioning of the discharge openings for the molding materials. In FIG. 5, in each case the flow lines during the filling of the cavity 13 are illustrated by thin continuous lines. For the first molding material 21, a total of seven flow lines a, b, c, d, e, f, g are drawn in. For the second molding material 22, five flow lines a2, b2, c2, d2 and e2 are drawn in. For the third molding material 24, eight flow lines a3, b3, c3, d3, e3, f3, g3 and h3 are drawn in. As a result of the shape of the guide element 7, angular in plan view, it can be ensured that the second molding material 22 fills the area between the discharge opening and the guide element 7, mixing with the third molding material 24 occurring in the area of the crenellations of the guide element 7. Otherwise, this exemplary embodiment corresponds to the previous exemplary embodiment, so that reference can be made to the description.

According to the invention, as described in the two exemplary embodiments, a method is thus provided for producing an electronic assembly which is produced from a plurality of molding materials. In this case, a specific shaped body 2 can be produced with reference to specific properties of individual electronic components by means of material choice and/or arrangement of separating elements 6, in particular completely closed separating elements, to produce areas free of molding compound, and/or by using guide elements 7. Both partial embedding of electronic components and also complete encapsulation are possible. The invention is particularly preferably used in conjunction with electronic assemblies for vehicles, for example control devices, sensors and so on.

1. A method for producing an electronic assembly (1) having at least one electronic component (3, 4) and a shaped body (2) at least partly surrounding the electronic component (3, 4), comprising the steps:
inserting at least one electronic component (3, 4) into an opened mold (10),
supplying a first molding material (21) and a second molding material (22) to a cavity (13) in the mold (10), the first molding material being different from the second molding material, and
closing the mold (10),
the mold (10) being closed before or at the same time as the first and second molding material (21, 22) are supplied.

2. The method as claimed in claim 1, characterized in that the first and second molding material (21, 22) are supplied simultaneously.

3. The method as claimed in claim 1, characterized in that the first molding material (21) is supplied by a first piston (18) and the second molding material (22) is supplied by a second piston (19).

4. The method as claimed in claim 1, characterized by a separating element (6), which is placed on the electronic component (3, 4) or which is fixed to the electronic component (3, 4), the separating element providing, with a mold wall (12a), a subdivision of the cavity (13) in the mold (10).

5. The method as claimed in claim 1, characterized by a guide element (7) for guiding the molding material supplied in the cavity (13), the guide element (7) being provided as an insert part and/or fixed to the mold and/or fixed to the electronic component.

6. The method as claimed in claim 1, characterized in that the first and second molding material (21, 22) are supplied to the mold (10) from mutually opposite sides.

7. An electronic assembly, comprising at least one electronic component (3, 4) and a shaped body (2) at least partly surrounding the electronic component (3, 4), the shaped body (2) comprising at least a first molding material (21) and a second molding material (22), and the first molding material (21) being different from the second molding material (22).

8. The assembly as claimed in claim 7, further comprising at least one separating element (6), which is arranged in the shaped body (2) and separates the first molding material (21) from the second molding material (22).

9. The assembly as claimed in claim 8, characterized in that the separating element is an electronic component or in that the separating element (6) is circumferentially closed, in order to form a cavity (30) in the shaped body (2).

10. The assembly as claimed in claim 7, further comprising at least one guide element (7) which is arranged in the shaped body (2), the guide element (7) having guided molding material in the cavity (13) of the mold (10).

11. The method as claimed in claim 1, characterized by a guide element (7) for guiding the molding material supplied in the cavity (13), the guide element (7) being provided as an insert part.

12. The method as claimed in claim 1, characterized by a guide element (7) for guiding the molding material supplied in the cavity (13), the guide element (7) being fixed to the mold.

13. The method as claimed in claim 1, characterized by a guide element (7) for guiding the molding material supplied in the cavity (13), the guide element (7) being fixed to the electronic component.
